(19) United States
(12) Patent Application Publication
(10) Pub. No.: US 2004/0048498 A1
(43) Pub. Date: Mar. 11, 2004

(54) Metallic surface mount technology power connector

(76) Inventors: Hong Huang, North Andover, MA (US); Allan Mark, Austin, TX (US)

Correspondence Address: DONALD L. BARTELS, COUDERT BROTHERS LLP, TWO PALO ALTO SQUARE FOURTH FLOOR, 3000 EL CAMINO REAL, PALO ALTO, CA, 94306-2121, US

(21) Appl. No.: 10/634,332

(22) Filed: Aug. 4, 2003

Related U.S. Application Data
(60) Provisional application No. 60/409,279, filed on Sep. 6, 2002.

(51) Int. Cl. H05K 1/00

(52) U.S. Cl. 439/66

(57) ABSTRACT

The present invention provides a metallic power connector for PCB-to-PCB attachment using surface mount technology. The connector has a cross section that is in the shape of a hollow trapezoid. Parallel sides of the trapezoid are adapted for connecting to contact pads on the PCBs with differently shaped footprints. The non-parallel sides of the trapezoid provide structural stability and rigidity not found in prior art SMT connectors. The inventive metallic SMT power connector allows for power and heat flow from a first PCB to a second PCB, and is compatible with automated SMT processes.

### FIELD OF THE INVENTION

The present invention relate to devices for providing power connections between pairs of printed circuit boards and, in particular, to a surface mount connector for connecting a power module to a motherboard.

### BACKGROUND OF THE INVENTION

Computers and other electronic devices often include a plurality of interconnected printed circuit boards (PCBs). For example, it is common for a computer to have a motherboard and one or more other boards that execute or perform specialized operations or tasks. Connections between PCBs allow for the transfer of power between boards, and/or for the transfer of information, such as data or control signals. Printed circuit boards can be connected through a board edge having conductors for plugging into a common bus, by mounting cable or ribbon connectors on the board, or by providing pads on pairs of boards to allow for direct board-to-board connection with surface mount technology (SMT) connectors.

For board-to-board PCB mounting, it is important that the boards are physically separated as well as electrically connected. It is also important that the boards be mechanically supported to prevent excessive movement of the boards. For power boards and boards that otherwise dissipate a large amount of power, the flow of heat between boards is also of concern. The electrical, physical, and mechanical functions can be provided separately, such as by mounting spacing devices to provide separation and mechanical support, and by providing connectors on each board and a cable to establish electrical connections between connectors. Alternatively, connectors that are designed to mate together can be attached to two boards opposite to each other to provide both electrical connections and physical separation support.

One method of providing electrical and physical functions with a connector is through the use of an SMT connector that allows for connection between adjoining surface areas of the PCBs. SMT connectors of this type are commonly formed of a thin metal sheet bent into a 4-sided, thin-walled structure, where the four sides form a rectangle. The resulting hollow structure has one pair of opposing sides (“attachment sides”) that have approximately equal contact areas for attaching to respective surfaces of the PCBS. The other pair of opposing sides of the SMT connectors provides electrical connections between the attachment sides.

Prior art SMT connectors for PCBs usually provide limited mechanical stability. The size of prior art contact pads on a PCB is usually kept small to reduce the contact pad footprint. The spacing of PCB boards is governed by the size of electrical components mounted on the boards and also possibly the need to allow airflow for cooling purposes. Thus, the height dimension of an SMT connector (dictated by the board spacing) is usually much larger than the width dimension (dictated by the contact pad size). Prior art SMT connectors thus are elongated rectangular structures attached to the boards along their smaller sides. As a result, these connectors provide electrical contact and spacing at the point of contact, but provide little lateral support. Even with multiple SMT connectors attaching two boards, it is common for there to be much lateral movement between the boards, especially when the boards are mounted vertically or they include relatively heavy components, such as power components.

What is needed is an improved SMT connector for PCBs. Such a connector should provide electrical contact with the amount of spacing required to accommodate components positioned between the PCBs, should constrain lateral movement of the boards while providing mechanical support for the connected PCBs, and should minimize the contact pad footprint on one or both of the connected PCBs. In addition, the connector should provide sufficient conductive heat transfer from the power PCB through the connector, and should be suitable for automated SMT processes without requiring additional machines or special feeders.

### SUMMARY OF THE INVENTION

The present invention solves the above-identified problems of known SMT connectors by providing a SMT connector adapted for connecting to two contact pads, one pad positioned on the surface of a respective PCB. The inventive connector has a shape that improves the mechanical stability of the board-to-board connection and allows for adequate current and heat flow from one PCB to the other PCB. In accordance with the present invention, a metallic SMT connector having a hollow cross-section is provided. The connector includes two sides that are substantially parallel and form a first portion congruent with at least a portion of a first contact pad and a second portion that is smaller than said first portion and congruent with at least a portion of said the second contact pad.

The connector includes a first pair of substantially parallel sides adapted for attaching to each of one contact pads on a separate PCB, and a second pair of sides that are not parallel and that span the distance between the first pair of sides. The second pair of sides provides electrical and thermal contact between the first pair of sides. In one embodiment of the present invention, the SMT connector has a hollow trapezoidal cross-section.

A further understanding of the invention can be had from the detailed discussion of the specific embodiment below. For purposes of clarity, this discussion refers to devices, methods, and concepts in terms of specific examples. However, the method of the present invention may be used to connect a wide variety of types of devices. It is therefore intended that the invention not be limited by the discussion of specific embodiments.

### BRIEF DESCRIPTION OF THE DRAWINGS

The foregoing aspects and the attendant advantages of the present invention will become more readily appreciated by reference to the following detailed description, when taken in conjunction with the accompanying drawings, wherein:

FIG. 1 is a perspective view of one embodiment of a metallic SMT connector according to the present invention as attached to a first circuit board;

FIG. 2 is a side view of an SMT power connector according to the present invention connected to two PCBs; and

FIG. 3 is a perspective view of the SMT power connector according to the present invention.

Reference symbols are used in the figures to indicate certain components, aspects or features shown therein, with reference symbols common to more than one figure indicating like components, aspects or features shown therein.

### DETAILED DESCRIPTION OF THE INVENTION

To facilitate its description, the invention is described below in terms of device configuration for providing a connection between two PCBs. In the example given, the first PCB is a DC-DC power module and the second board is a computer motherboard. In general, the present invention is a device for providing connection between two boards using surface mount technologies, and should therefore not be taken as limited except as provided in the attached claims.

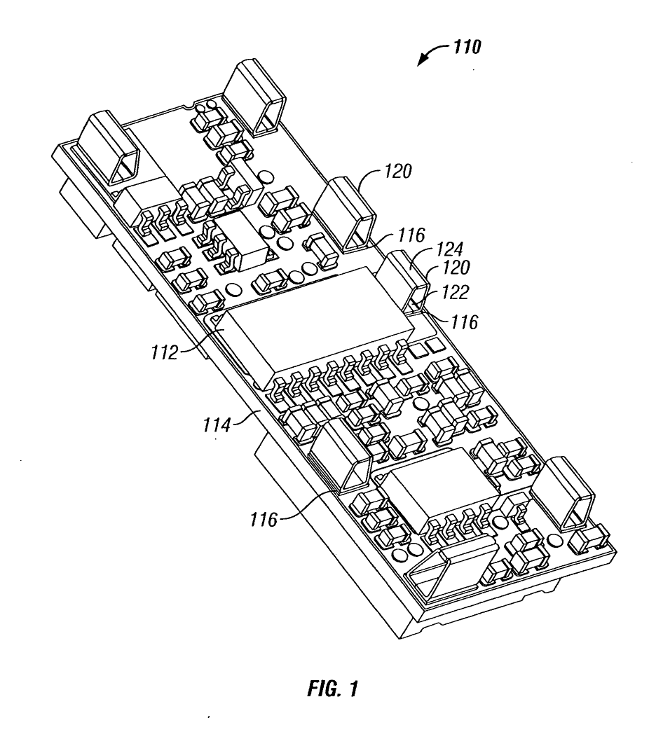

The present invention will now be described in more detail with reference to the figures. FIG. 1 is a perspective view of an embodiment of the present invention as an SMT connector 120 attached to a first PCB 114. Specifically, FIG. 1 shows DC-DC module 110 having components 112 on PCB 114. The surface of PCB 114 also has several contact pads 116 disposed thereon. Each contact pad 116 is in turn connected to one or more components 112, as dictated by the circuit being implemented by the PCB and components 112, and is provided to enable electrical signals to be coupled onto and off of module 110 via respective connectors 120. Examples of such signals may include, but are not limited to power and control signals to and from module 110. Contact pads 116 may also be used to conduct heat off of PCB 114 via connectors 120. Attached to each contact pad 116 is an SMT connector 120 having first and second sides 122 and 124 adapted for attaching to a contact pad 116 on one of the PCBs. FIG. 1 shows each SMT connector 120 attached to a contact pad 116 at side 122. The plurality of sides 124 are positioned for the mounting of a second PCB, which is not shown in FIG. 1. SMT connector 120 is preferably a metallic connector.

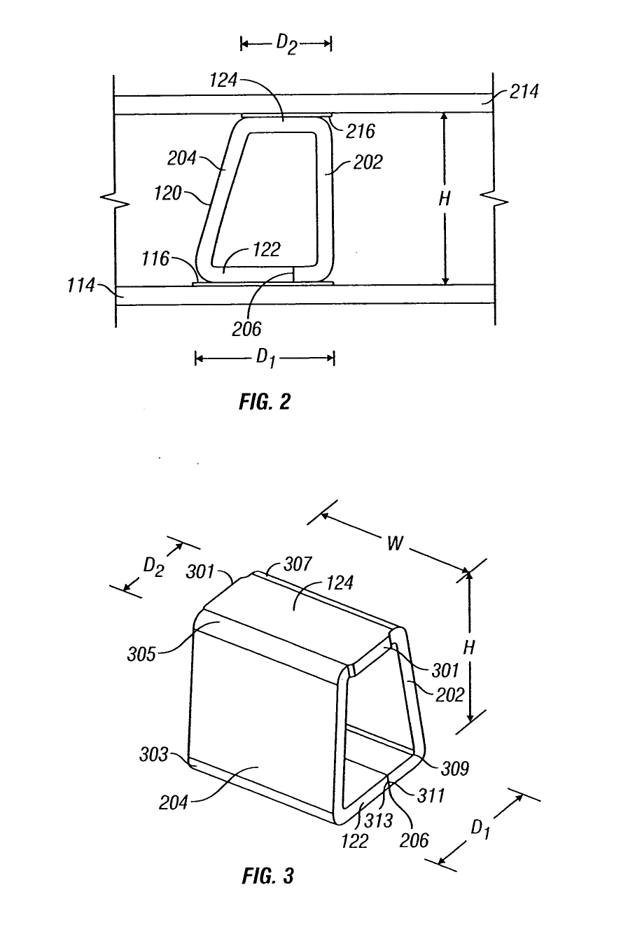

FIG. 2 is a side view of SMT power connector 120 attached to PCB 114 and to a motherboard PCB 214. FIG. 3 is a perspective view of connector 120. As shown in FIG. 2, connector 120 is attached to PCB 214 at a contact pad 216. Contact pad 116 is also shown in FIG. 2 for attaching connector 120 to PCB 114. Connector 120 has, in addition to sides 122 and 124, a pair of sides 202 and 204 to provide electrical contact between PCBs 114 and 214 and mechanical support for PCBs 114 and 124. Sides 122 and 124 are parallel, with a spacing H, and have different nominal depths D1 and D2, respectively. The height H provides sufficient spacing for any components on either of boards 114 and 214 that face the other board, and to provide space for any cooling that is required. Providing two or more connectors 120 between PCBs 114 and 214 thus spaces the PCBs parallel to each other with spacing H.

As shown in FIG. 3, connector 120 has a width W, and thus sides 122 and 124 have different rectangular-shaped footprints for attachment to contact pads 116 and 216, respectively as a function of the difference in depths D1 and D2. Since sides 122 and 124 are of different depths (D1 and D2, respectively), connector 120 has a trapezoidal shape in cross-section. The use of a connector of a hollow, trapezoidal shape has advantages over prior art connectors, which typically are shaped to create a hollow rectangular shape. A first advantage of a trapezoidal connector that attaches on the parallel faces is that two footprints of differing size can be provided. Thus, for example, connection can be made to motherboard 214 via a small footprint, while connection is made to DC-DC module 114 via a more stable, larger footprint. A second advantage of a trapezoidal connector is that it is structurally more resistant to lateral movements of the PCBs than a rectangular connector. A rectangular connector can easily fold or collapse when opposite sides are moved parallel to one another. A trapezoidal connector is more rigid as the sides of different length resist the folding or collapsing of the connector.

As also seen in FIG. 3, the hollow structure of connector 120 may be formed from a strip of material of width W and length that extends from a first end 311 to a second end 313. The strip is bent along edges 303, 305, 307 and 309 to form sides 122, 204, 124, and 202. In this example, the width of the strip is approximately 2.6 mm and the length is approximately 8 mm. When folded, ends 311 and 313 abut along seam 206. Individual connectors are formed from a continuous strip of material, and the cutting of the material usually results in a pair of carry tabs 301 on the connector. Connector 120 is also preferably solder plated prior to attachment to PCBs 114 and 214 to provide for easier attachment.

The material and dimensions of connector 120 are selected for each application to provide not only mechanical support for the PCBs, but also to provide for adequate conductive heat transfer and electrical current capacity from one board to the other, such as from a heat generating DC-DC module 110 to a motherboard. Since the trapezoidal shape of connector 120 provides added mechanical stability over prior art rectangular-shaped connectors, connector 120 can be constructed of softer materials and/or can have thinner walls than prior art rectangular-shaped connectors, e.g., less than 0.3 mm and in this example is about 0.2 mm in thickness. The material of connector 120 is preferably a high conductivity material, such as copper, though other conductors, such as metals or alloys may be used.

The inventive connectors are easily incorporated into SMT manufacturing processes. For example, a plurality of connectors 120 can be provided on a tape and real for feeding into an SMT assembly line. Alternatively, connectors 120 can be manufactured in conjunction with the SMT manufacturing assembly of PCBs from sheet metal, for example. Through the additional step of forming the connectors and the use of a custom feeder, connectors 120 can be provided directly to a pick and place head, eliminating the costs and assembly of a tape and reel.

The invention has now been explained with regard to specific embodiments. Variations on these embodiments and other embodiments may be apparent to those of skill in the art. It is therefore intended that the invention not be limited by the discussion of specific embodiments. It is understood that the examples and embodiments described herein are for illustrative purposes only and that various modifications or changes in light thereof will be suggested to persons skilled in the art and are to be included within the spirit and purview of this application and scope of the appended claims.

What is claimed is:

1. A surface mount technology connector for mounting between a first printed circuit board having a first contact area and a second printed circuit board having a second contact area, said connector comprising:
a member having a hollow cross-section, where two sides of said member are substantially parallel and form a first portion congruent with at least a portion of said first contact area and a second portion that is smaller than said first portion and congruent with at least a portion of said second contact area.

2. The connector of claim 1, wherein said member forms a trapezoidal cross-section.

3. The connector of claim 2, wherein said member is formed from a strip of material of a given width and a given length that extends from a first end of the strip that forms a part of the first portion that is congruent with at least a portion of the first contact area to a second end of the strip that forms the remaining part of the first portion.

4. The connector of claim 3, wherein said first end abuts said second end to form a seam therebetween of the given width.

5. The connector of claim 3, wherein tabs are formed on either side of said second contact area.

6. The connector of claim 3, wherein the material is a highly conductive metal.

7. The connector of claim 6, wherein the material is copper.

8. The connector of claim 7, wherein the material is plated with solder prior to attachment to the printed circuit boards.

9. The connector of claim 1, wherein power and heat are allowed to flow between the first and second printed circuit boards.

10. A surface mount technology connector for providing power to flow between a first printed circuit board having a first contact area and a second printed circuit board having a second contact area, said connector comprising:
a member having a hollow trapezoidal cross-section, where a strip of a highly conductive metal having a given width and a given length is bent along four separate edges to form the trapezoidal cross-sectional member having first and second substantially parallel sides and two non-parallel sides, where the first substantially parallel side has a first portion that is congruent with at least a portion of said first contact area and the second substantially parallel side has a second portion that is congruent with at least a portion of said second contact area, and where a first end of the strip forms a part of the first substantially parallel side and a second end of the strip forms the remaining part of the first substantially parallel side and abuts the first end to from a seam there between.

11. The connector of claim 10, wherein tabs are formed on either side of said second substantially parallel side.

12. The connector of claim 10, wherein the material is a highly conductive metal.

13. The connector of claim 12, wherein the material is copper.

14. The connector of claim 13, wherein the material is plated with solder prior to attachment to the printed circuit boards.

15. The connector of claim 10, wherein the thickness of the strip is less than 0.3 mm.
